(19) United States
(12) Patent Application Publication
(10) Pub. No.: US 2007/0001301 A1
(43) Pub. Date: Jan. 4, 2007

(54) Under bump metallization design to reduce dielectric layer delamination

(76) Inventor: Yongqian Wang, Gilbert, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/148,599

(22) Filed: Jun. 8, 2005

(51) Int. Cl. H01L 23/48

(52) U.S. Cl. 257/734

(57) ABSTRACT

An under-bump metallization (UBM) design comprises a semiconductor chip having a plurality of interconnect layers, a passivation layer atop the plurality of interconnect layers, and a UBM layer atop the passivation layer, wherein a surface of the UBM layer comprises at least a first area recessed into the passivation layer and a second area recessed into the passivation layer. A metal bump may be formed atop the UBM layer. A center portion of the metal bump is mounted within the first area while an anchor portion of the metal bump is mounted within the second area.

### BACKGROUND

The controlled collapse chip connection (C4), also known as the “flip-chip” connection, is a configuration by which a semiconductor chip can be coupled to a carrier, for example, a computer motherboard. A C4 configuration uses an array of solder bumps or balls that are arranged around the surface of the semiconductor chip, either in an area array or a peripheral configuration. The semiconductor chip is placed face down on the carrier. When heat is applied, the solder bumps reflow to the integrated circuit pads (IC pads) joining the semiconductor chip to the carrier. A C4 configuration provides high input/output density, uniform chip power distribution, improved cooling capability, and high reliability. C4 technology has also increased packaging density, data bandwidths, and operating frequencies while reducing system-level noise.

A critical issue that is challenging the whole microelectronics industry is the delamination of inter-level dielectric (ILD) layers on a semiconductor chip below the IC pad in a C4 process. This is a particularly large problem for delicate, conventional low-k dielectric layers and brittle, porous low-k dielectric layers. Low-k delamination is generally caused by a high stress concentration that is present under the IC pad after the C4 connection is made. With current designs, the load upon the ILD layers directly beneath the IC pad is highly concentrated due to shear stresses from thermal expansion mismatches and normal stresses due to warping behavior. Because the use of porous low-k dielectric materials is becoming standard in the industry, improved designs are needed to reduce the delamination of ILD layers.

### BRIEF DESCRIPTION OF THE DRAWINGS

FIG. 1 illustrates a conventional C4 configuration.

FIG. 2 illustrates a novel UBM layer in accordance with an implementation of the invention.

FIG. 3 illustrates a novel UBM layer in accordance with another implementation of the invention.

FIGS. 4A and 4B are top views of an under-bump metallization layer having multiple column anchors in accordance with implementations of the invention.

FIGS. 5A and 5B are top views of an under-bump metallization layer having ring anchors in accordance with implementations of the invention.

FIG. 6A illustrates an implementation of the invention where the integrated circuit pad extends to the anchors.

FIG. 6B illustrates an implementation of an integrated circuit pad that extends to multiple column anchors.

FIG. 6C illustrates an implementation of an integrated circuit pad that extends to a ring anchor.

### DETAILED DESCRIPTION

Described herein are systems and methods of reducing the delamination of inter-level dielectric (ILD) layers during and after controlled collapse chip connection (C4) processes. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

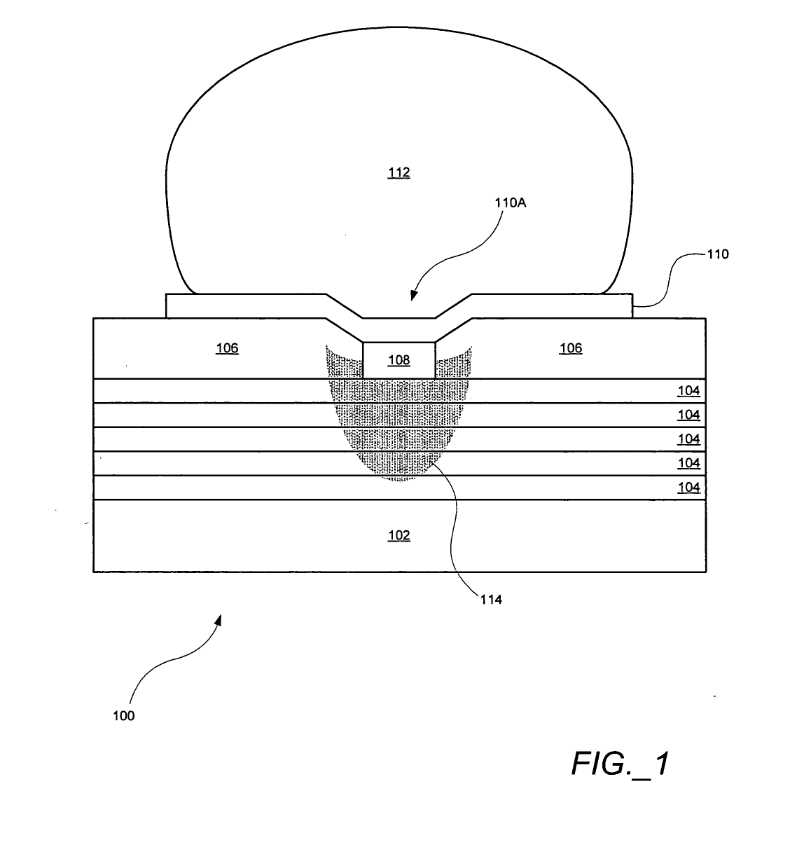

FIG. 1 illustrates a conventional C4 configuration. A semiconductor chip 100 is shown, wherein the semiconductor chip 100 includes a semiconductor substrate 102. Formed on or within the semiconductor substrate 102 are devices such as transistors, capacitors, and interconnects (not shown). On a top surface of the semiconductor substrate 102 are formed multiple interconnect layers 104 that serve to further interconnect the various devices on the semiconductor substrate 102. The interconnect layers 104 may include metallization layers consisting of metal interconnects separated by dielectric material. The interconnect layers 104 may also include inter-level dielectric (ILD) layers used to separate and insulate the metallization layers from one another. Vias may penetrate through the ILD layers to connect the metallization layers together. The interconnected devices form an integrated circuit (IC).

A passivation layer 106 is generally formed atop the final interconnect layer 104. The passivation layer 106 seals and protects the integrated circuit and interconnect layers 104 from damage and contamination. The passivation layer 106 may be formed from many different materials, including but not limited to polyimide. The passivation layer 106 may be formed using well known processes in the art that include, but are not limited to, chemical vapor deposition (CVD), plasma enhanced chemical vapor deposition (PECVD), spin-on processes, etc.

Openings may be etched in the passivation layer 106 allowing electrical elements in the environment outside of the semiconductor chip 100 to access the interconnect layers 104, for instance, electrical probes and/or wire bonds that are part of a carrier (e.g., a motherboard) upon which the semiconductor chip 100 is mounted. One or more integrated circuit pads (IC pads) 108 may be formed within such openings through the passivation layer 106. The IC pads 108 may then couple metallization layers within the interconnect layers 104 to electrical elements outside of the semiconductor chip 100. The IC pad 108 may be formed using a metal such as copper or aluminum.

A conventional under-bump metallization (UBM) layer 110 is formed atop the IC pad 108 and the passivation layer 106 in the C4 configuration of FIG. 1. The UBM layer 110 is generally a layer of one or several metals over the IC pad 108 and is used to create a barrier between the fragile IC pad 108 and a metal bump 112. Metals used for the UBM layer 110 include, but are not limited to, one or more of copper, aluminum, nickel, titanium, and chromium. The metals used in the UBM layer 110 must be electrically conductive to pass current between the IC pad 108 and the metal bump 112. The UBM layer 110 may be formed using well known processes in the art that include, but are not limited to, CVD, physical vapor deposition (PVD), atomic layer deposition (ALD), PECVD, sputtering deposition, electroplating, and electroless plating. As shown in FIG. 1, the UBM layer 110 has a center portion 110A that is recessed into the passivation layer 106 relative to the metal bump 112. The recessed center portion 110A provides a seat within which the metal bump 112 may rest.

The metal bump 112, resting atop the UBM layer 110, provides the final electrical connection between the interconnect layers 104 and the environment outside of the semiconductor chip 100. The metal bump 112 is generally formed using a metal such as copper, a copper alloy, or an alloy of lead and tin. The metal bump 112 may be formed using well known processes in the art that include, but are not limited to, CVD, PVD, ALD, PECVD, electroplating, and electroless plating. In a typical C4 process, the solder bumps on a substrate or other carrier are aligned with the metal bumps 112 and are reflowed to form joints. The metal bump 112 generally fills several important functions. For example, because it is very difficult to directly attach electrical wires between a carrier and thin, small IC pads 108, metal bumps 112 provide a medium through which such connections can be made. Furthermore, metal bumps 112 provide a standoff that can produce a controlled gap between the semiconductor chip 100 and a carrier substrate. If the interconnect length is close to zero, any thermal expansion mismatch will cause extreme stress concentrations. The metal bump 112 acts as a short lead to relieve these stresses. Another important function is the metal bumps 112 help reduce openings and improve the yield of a C4 process.

Unfortunately, the conventional UBM layer 110 design illustrated in FIG. 1 tends to produce a great deal of stress on the portions of the interconnect layers 104 directly below the metal bump 112. With conventional UBM layer 110 designs, a concentrated load 114 is created due to shear stresses from thermal expansion mismatches and normal stresses due to warpage. Since the center portion 110A penetrates into the passivation layer 106 and is located directly on top of the IC pad 108, this load 114 is highly concentrated in the region right below the IC pad 108. There may also be an even higher stress concentration present along the perimeter of the UBM layer 110 (not shown). This is particularly true when there is an undercut or overhang between the UBM layer 110 and the passivation layer 106, which may form during the fabrication process, for instance, during the etching of the UBM layer 110.

This load 114 is one of the primary causes of low-k dielectric interconnect layer delamination. It should be noted that the actual profile or shape of the load 114 will vary based on a number of variables, including but not limited to the materials used, the size and thicknesses of each of the layers shown in FIG. 1, and the pressures applied during and after the semiconductor chip 100 is coupled to a carrier using the C4 process. Therefore, the load 114 pictured in FIG. 1 is simply for illustrative purposes and is not intended to show the precise profile of the load 114.

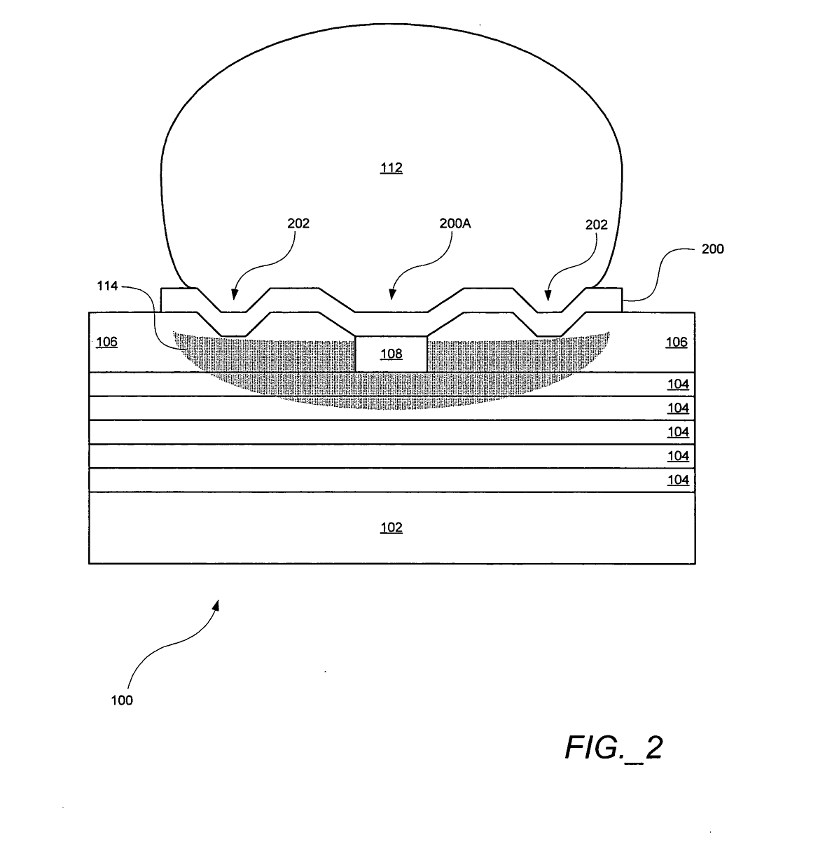

FIG. 2 illustrates an implementation of the invention in which a novel UBM layer is utilized to redistribute the load created by the shear and normal stresses. The semiconductor chip 100 of FIG. 2 still consists of a semiconductor substrate 102 having multiple interconnect layers 104 formed thereon. The passivation layer 106 is formed atop the interconnect layers 104 with one or more openings for IC pads 108.

The implementation shown in FIG. 2 utilizes a novel UBM layer 200 having one or more anchors 202. The anchors 202 consist of recessed areas formed in the UBM layer 200 that are in addition to a recessed center portion 200A. The same load 114 is created by the metal bump 112 due to the shear and normal stresses, but because the anchors 202 are recessed into the passivation layer 106, portions of this load 114 are now redistributed away from the center portion 200A and to the anchors 202. Since the anchors 202 are spaced apart from the center portion 200A, the same load 114 now becomes redistributed over a larger volume, as shown in FIG. 2. This causes the stress magnitude on portions of the interconnect layers 104 below the IC pad 108 to be significantly decreased, thereby reducing the likelihood of low-k dielectric layer delamination. In some implementations, the low-k dielectric layer delamination may be reduced or even eliminated if the stress concentration can be effectively reduced. Again, for the reasons described above, the load 114 pictured in FIG. 2 is simply for illustrative purposes and is not intended to show the precise profile of the load 114.

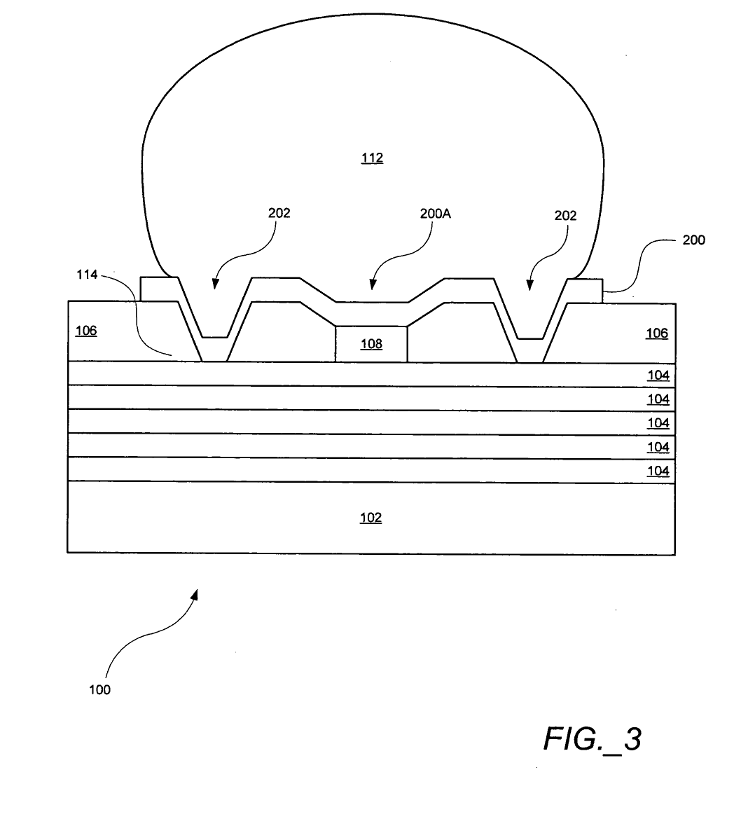

In some implementations of the invention, the anchors 202 may be shallow and penetrate into a top portion of the passivation layer 106, as shown in FIG. 2. In alternate implementations, the anchors 202 may penetrate more deeply into the passivation layer 106, and may even come into contact with the final interconnect layer 104. This alternate implementation is illustrated in FIG. 3. In this case, the magnitude of the stress concentration below the UBM 110 is lower.

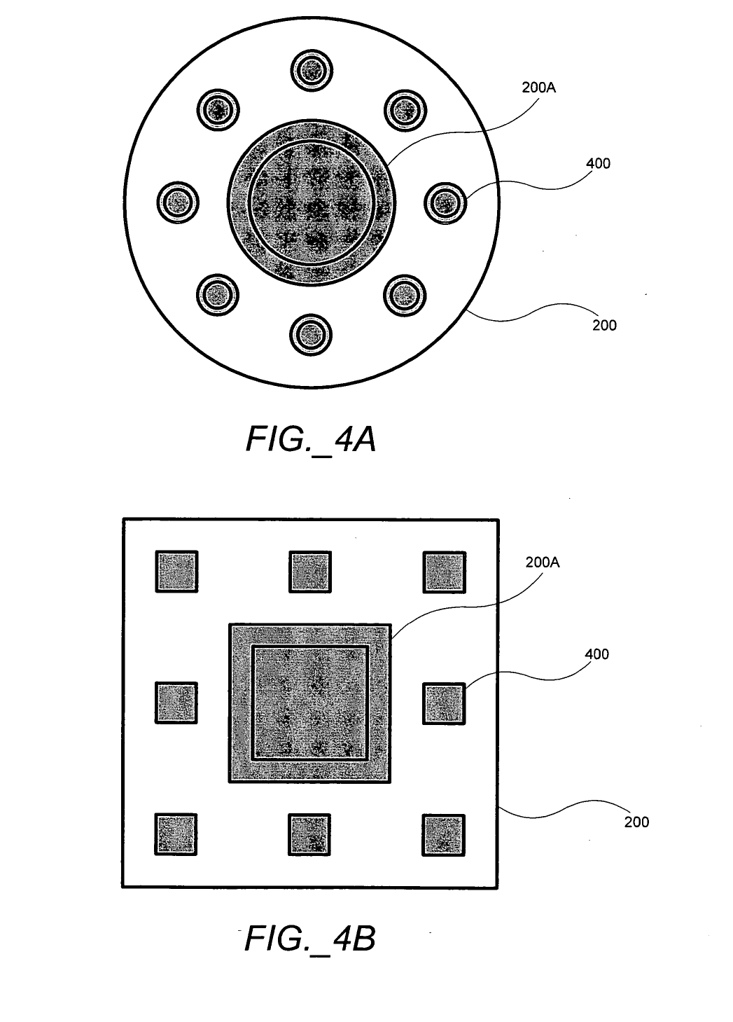

FIGS. 4A and 4B are top views of the UBM layer 200 showing multiple anchors 400 oriented around the perimeter of the center portion 200A. FIGS. 4A and 4B illustrate an implementation of the invention where the anchors are column anchors 400. In FIGS. 4A and 4B, the column anchors 400 and the center portion 200A are shaded for clarity (i.e., the recessed areas on the UBM layer 200 are shaded).

Column anchors 400 are individual, discontinuous anchors that surround the center portion 200A. In some implementations, the column anchors 400 may have a generally cylindrical or conical form factor. For example, the anchors 202 shown in FIGS. 2 and 3 have a generally conical form factor. In other implementations, the column anchors 400 may have a shape other than cylindrical or conical, for instance, the column anchors 400 may have a cubical form factor.

In FIG. 4A, the UBM layer 200 has a circular shape, accordingly, the center portion 200A has a corresponding circular shape and the column anchors 400 are arranged in a circular pattern. The column anchors 400 have a generally conical form factor in FIG. 4A. In alternate implementations, the UBM layer 200 and/or the center portion 200A may have shapes that are not circular. In those implementations, the column anchors 400 may be oriented around a perimeter of the center portion 200A as appropriate. For instance, FIG. 4B illustrates a generally square-shaped UBM layer 200 with a square-shaped center portion 200A. In such an implementation, the column anchors 400 may be arranged in a square shaped pattern around the center portion 200A. The column anchors 400 may have a cubical form factor, as shown in FIG. 4B, or they may have the cylindrical or conical form factor shown in FIG. 4A. The shape of the column anchor 400 does not necessarily match the shape of the UBM layer 200 and/or the center portion 200A.

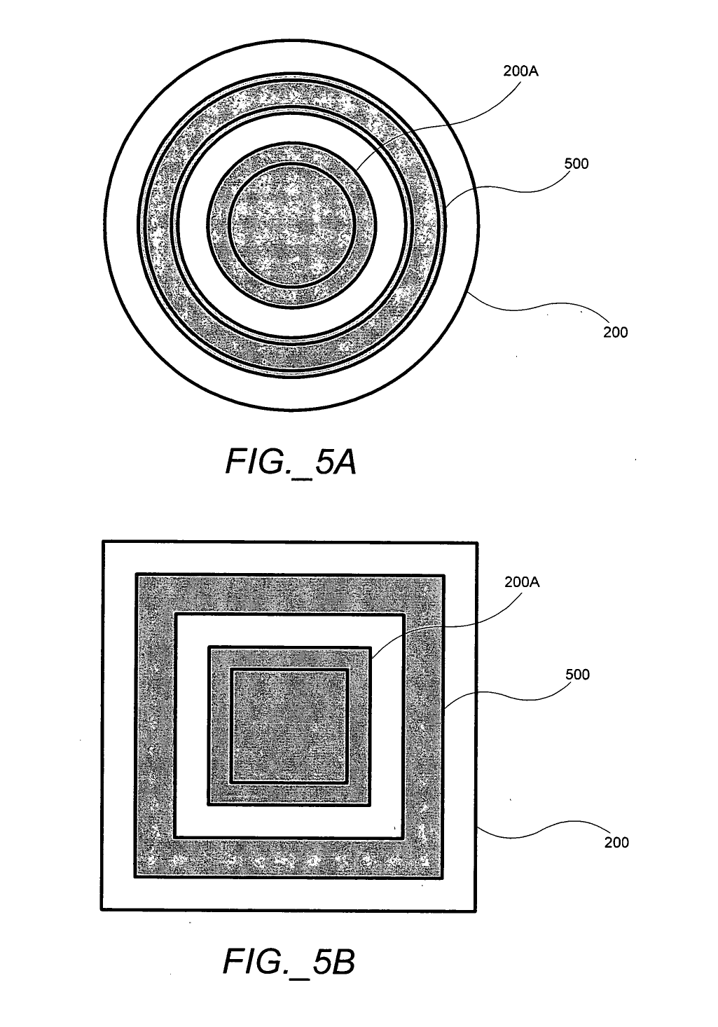

FIGS. 5A and 5B illustrate another implementation of the invention. FIG. 5A is a top view of the UBM layer 200 showing a ring anchor 500 oriented around the perimeter of the center portion 200A. The ring anchor 500 is a single, continuous anchor that encloses the center portion 200A. In FIGS. 5A and 5B, the ring anchor 500 and the center portion 200A are shaded for clarity (i.e., the recessed areas on the UBM layer 200 are shaded). In some implementations, the ring anchor 500 may have a generally circular or square-shaped form factor. In other implementations, the ring anchor 500 may take on the shape of any polygon that is able to enclose the center portion 200A. The ring anchor 500 may have a tapered cross-section so the top opening of the ring anchor 500 is wider than a bottom surface of the ring anchor 500. This is shown in FIGS. 2 and 3 where the anchors 202 also represent a cross-section of a tapered ring anchor 500. In FIG. 5A, the ring anchor 500 has a circular shape with a tapered cross-section. In FIG. 5B, a top view of the UBM layer 200 is shown where the ring anchor 500 has a square shape with a non-tapered cross-section.

In implementations of the invention, the anchors 202 are formed by appropriately etching the passivation layer 106 prior to depositing the UBM layer 200. In other implementations of the invention, the anchors 202 may be grown into the passivation layer 106.

In some implementations, fabrication of the anchors 202 (including the column anchors 400 and the ring anchors 500) may be performed using standard photolithography and etching techniques. The photolithography masks used for etching the UBM layer 200, for etching the IC pads 108, and/or patterning the metal bump 112 may be modified to open up apertures for the anchors 202, such as the column anchors 400 and the ring anchors 500. Such fabrication processes are generally compatible with conventional technology.

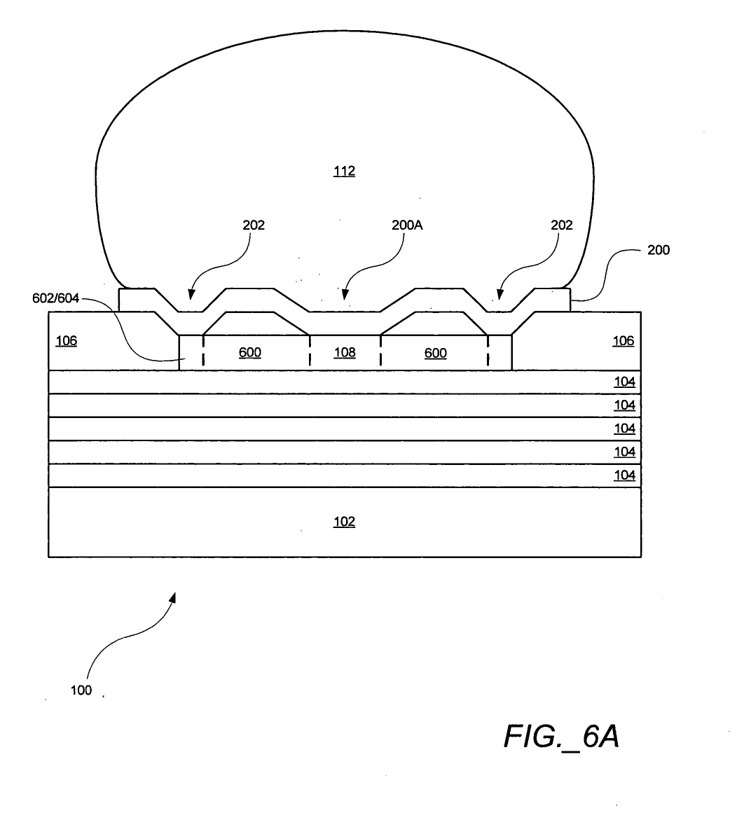

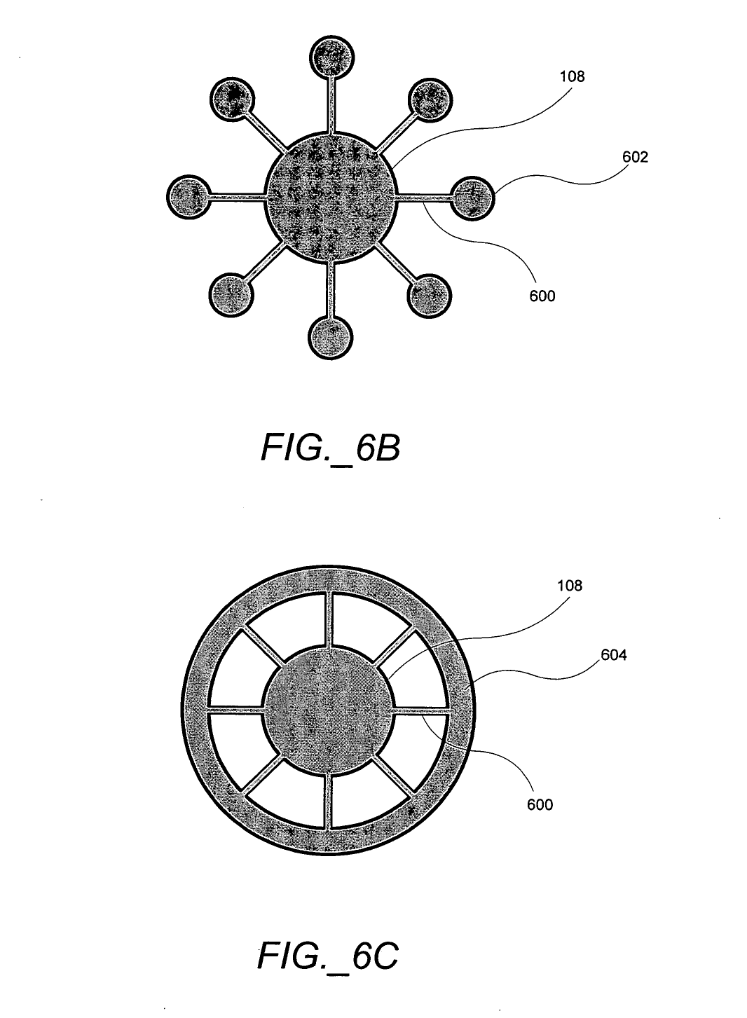

FIG. 6A illustrates another implementation of the invention where the IC pad 108 extends to the anchors 202 (including the column anchors 400 and the ring anchors 500). This implementation provides a larger surface area for electrical current to pass between the carrier and the semiconductor chip 100, thereby taking advantage of the presence of the anchors 202 and reducing the risk of electromigration. This may also help in further redistributing the load created by the shear and normal stresses.

FIG. 6B illustrates a top view of the implementation of the IC pad 108 shown in FIG. 6A for use with the column anchors 400. FIG. 6B shows the IC pad 108 prior to deposition of any subsequent layers such as the passivation layer 106 or the UBM layer 200. The IC pad 108 may include column pads 602 upon which the column anchors 400 are formed, as well as separate extensions 600 to each of the pads 602. When the passivation layer 106 is deposited, the extensions 600 become covered and only the IC pad 108 and the column pads 602 will be available to the UBM layer 200, as shown in FIG. 6A.

FIG. 6C illustrates a top view of the implementation of the IC pad 108 shown in FIG. 6A for use with the ring anchor 500. FIG. 6C shows the IC pad 108 prior to deposition of any subsequent layers such as the passivation layer 106 or the UBM layer 200. In this implementation, the IC pad 108 may include a ring pad 604 upon which the ring anchor 500 may be formed. One or more extensions 600 may be used to couple the IC pad 108 to one or more portions of the ring pad 604. When the passivation layer 106 is deposited, the extensions 600 become covered and only the IC pad 108 and the ring pad 604 are available to the UBM layer 200, as also shown in FIG. 6A.

Accordingly, implementations of UBM layers 200 utilizing anchors 202, such as column anchors 400 and ring anchors 500, have been disclosed. These implementations use the anchors to redistribute the load 114 created by the metal bump 112 and the C4 process over a larger volume of the passivation layer 106 and the interconnect layers 104, thereby minimizing the likelihood of delamination of the interconnect layers 104. The load is therefore no longer concentrated on the region directly below the IC pad 108. It should be noted that in implementations of the invention, the actual dimensions of the anchors, such as the depth and diameter, may be determined by modeling and trial experiments. The required dimensions will typically vary based on the materials used, the size of the semiconductor chip 100, and various other factors.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
a semiconductor chip having a plurality of interconnect layers;
a passivation layer atop the plurality of interconnect layers;
an under-bump metallization (UBM) layer atop the passivation layer, wherein a surface of the UBM layer comprises at least a first area recessed into the passivation layer and a second area recessed into the passivation layer; and
a metal bump formed atop the UBM layer.

2. The apparatus of claim 1, wherein the UBM layer comprises one or more layers of metal.

3. The apparatus of claim 1, wherein the first recessed area comprises a center portion of the UBM layer in which the metal bump sits.

4. The apparatus of claim 3, wherein the second recessed area comprises an anchor portion of the UBM layer in which the metal bump sits that enables a redistribution of a stress load created by the metal bump.

5. The apparatus of claim 4, wherein the UBM layer comprises a plurality of anchor portions oriented around the center portion.

6. The apparatus of claim 4, wherein the anchor portion comprises a column anchor.

7. The apparatus of claim 5, wherein the plurality of anchor portions comprise a plurality of column anchors.

8. The apparatus of claim 4, wherein the anchor portion comprises a ring anchor.

9. The apparatus of claim 8, wherein the ring anchor comprises a continuous recessed area that surrounds the center portion.

10. The apparatus of claim 1, wherein the second recessed area penetrates through the passivation layer down to the interconnect layers.

11. The apparatus of claim 1, wherein the passivation layer comprises a polyimide.

12. The apparatus of claim 1, wherein the metal bump comprises copper, a copper alloy, or a lead-tin alloy.

13. An apparatus comprising:
a semiconductor chip having a plurality of interconnect layers;
a passivation layer atop the plurality of interconnect layers; and
an under-bump metallization (UBM) layer atop the passivation layer, wherein the UBM layer comprises a center portion and at least one anchor portion.

14. The apparatus of claim 13, wherein the anchor portion comprises a column anchor.

15. The apparatus of claim 14, wherein the column anchor comprises a discrete area in the UBM layer that is recessed into the passivation layer.

16. The apparatus of claim 15, wherein the column anchor has a cylindrical form factor.

17. The apparatus of claim 15, wherein the column anchor has a conical form factor.

18. The apparatus of claim 15, wherein the column anchor has a cubic form factor.

19. The apparatus of claim 15, wherein the column anchor is recessed into a shallow portion of the passivation layer.

20. The apparatus of claim 15, wherein the column anchor is recessed into a deep portion of the passivation layer.

21. The apparatus of claim 13, wherein the anchor portion comprises a ring anchor.

22. The apparatus of claim 21, wherein the ring anchor comprises a continuous area in the UBM layer that is recessed into the passivation layer and surrounds the center portion.

23. The apparatus of claim 22, wherein the ring anchor tapers as it recesses into the passivation layer.

24. The apparatus of claim 22, wherein the ring anchor is recessed into a shallow portion of the passivation layer.

25. The apparatus of claim 22, wherein the ring anchor is recessed into a deep portion of the passivation layer.

26. A method comprising:
providing a semiconductor substrate having at least one interconnect layer and a passivation layer;
etching the passivation layer to form a first recessed area and a second recessed area;
depositing an under-bump metallization (UBM) layer atop the passivation layer and the first and second recessed areas; and
forming a metal bump atop the UBM layer, wherein portions of the metal bump are formed within the first recessed area and the second recessed area.

27. The method of claim 26, wherein the etching of the passivation layer is performed using standard photolithography and etching techniques.

28. The method of claim 26, wherein a center portion of the metal bump is formed within the first recessed portion and an anchor portion of the metal bump is formed within the second recessed area.

29. The method of claim 26, wherein the etching of the passivation layer further comprises etching the passivation layer to form a plurality of second recessed areas, wherein the plurality of second recessed areas form a perimeter around the first recessed area.

30. The method of claim 26, wherein the first and second recessed areas are etched through the passivation layer and contact the at least one interconnect layer.
